(19) United States
(12) Patent Application Publication
(10) Pub. No.: US 2003/0185331 A1
(43) Pub. Date: Oct. 2, 2003

(54) Synchronization module and method

(75) Inventors: Abaron M. Agizim, Nelanya (IL); Zadok Rachamim, Elad (IL)

Correspondence Address: Fogg Slifer Polglaze Leffert & Jay, P.A., P.O. Box 581009, Minneapolis, MN, 55458-1009, US

(73) Assignee: ADC Telecommunications Israel Ltd.

(21) Appl. No.: 10/109,336

(22) Filed: Mar. 28, 2002

(51) Int. Cl. H03D 3/24

(52) U.S. Cl. 375/376

(57) ABSTRACT

A method and apparatus for generating a stable high frequency clock from a low frequency reference signal performs most of its operations in a digital environment. The method and apparatus reduce complexity and cost by reducing the number of digital to analog and analog to digital conversions and eliminating synchronous counters.

### TECHNICAL FIELD

The present invention relates generally to telecommunications, and more specifically to clocking in telecommunications applications.

### BACKGROUND

Numerous solutions exist for the resolution of providing a high frequency clock following a low frequency reference. Known solutions include expensive parts, or complex hardware, and have numerous disadvantages. For example, a prior art solution 100 is shown in FIG. 1. This solution is expensive to implement. It does have disturbance robustness, that is it responds well to disturbances. However, the design is quite complicated and expensive. The counters of the solution 100 must have synchronous design because the latches store the status of a running counter. In order to implement this synchronous counter design, a complex hardware scheme is required. Further, the solution 100 contains no reference jitter reduction because all intermediate results in the system remain unused.

Another solution 200 is shown in FIG. 2. This solution is also expensive, as it relies on expensive parts. The parts, however, are conventional and available parts. The design is also robust with respect to disturbances. However, the solution 200 uses a double external phase locked loop (PLL) which results in extra inaccuracy. Further inaccuracy is introduced into the solution 200 from the multiple conversions between time to voltage and voltage to number conversions.

Both solutions 100 and 200 are based on production of a high frequency stable clock by means of an analog voltage. Each design requires conversion more than once from an analog signal to a digital signal, and back to an analog signal. These mixed signal solutions require greater than one conversion between analog and digital signals. In order to accomplish this multiple conversion, critical and expensive components are required.

For the reasons stated above, and for other reasons stated below which will become apparent to those skilled in the art upon reading and understanding the present specification, there is a need in the art for improvements in clock synchronization circuits, and for the reduction of complex design and components specifications.

### SUMMARY

In one embodiment, a method for generating stable high frequency signal from a low frequency reference clock signal includes receiving the reference clock signal and a divided down high frequency signal at a frequency to number converter, and generating a number in the frequency to number converter that is proportional to a difference in frequency between the divided down high frequency signal and the reference clock. A new high frequency signal is generated from the number.

In another embodiment, a method for generating a stable clock signal from an external reference clock includes receiving the reference clock signal at a signal to number converter, and converting the reference clock to a number proportional to a frequency difference between the reference clock signal and a generated clock signal. The number is received at a direct digital synthesizer (DDS), an analog representation of the number is generated, filtered, and converted to a logical output signal. The logical output signal is divided in frequency to the frequency of the reference clock and is fed to the frequency to number converter.

In still another embodiment, a synchronization module includes a direct digital synthesizer (DDS) having a first input and a clock input, and an output, a frequency to number converter having a first and a second input, the first input connectable to a reference clock signal, and an output, a digital filter connected between the DDS and the frequency to number converter output, a divider connected between the DDS output and the second input of the frequency to number converter, and a first phase locked loop for generating a clock signal, the clock signal connected to the clock input of the DDS.

In another embodiment, a direct digital synthesizer includes a digital synthesizer having a data input, a clock input, and an output, a band pass filter connected to the output of the digital synthesizer, and a comparator connected to an output of the band pass filter.

In yet another embodiment, a temperature compensated direct digital synthesizer (DDS) includes a digital synthesizer having a data input, a clock input, and an output, a band pass filter connected to the output of the digital synthesizer, a comparator connected to an output of the band pass filter, and a temperature module providing a feed forward temperature compensation (FFTC) signal from a look-up table to adjust the data input to the digital synthesizer, the FFTC signal indicative of frequency changes due to temperature while a reference clock falls.

Other embodiments are described and claimed.

### BRIEF DESCRIPTION OF THE DRAWINGS

FIG. 1 is a block diagram of a prior art solution;

FIG. 2 is a block diagram of another prior art solution;

FIG. 3 is a block diagram of a synchronization module according to an embodiment of the present invention;

FIG. 3A is a block diagram of a temperature compensation module according to another embodiment of the present invention;

FIG. 4 is a block diagram of a frequency to number converter according to another embodiment of the present invention; and

FIG. 5 is a timing diagram for the frequency to number converter of FIG. 4.

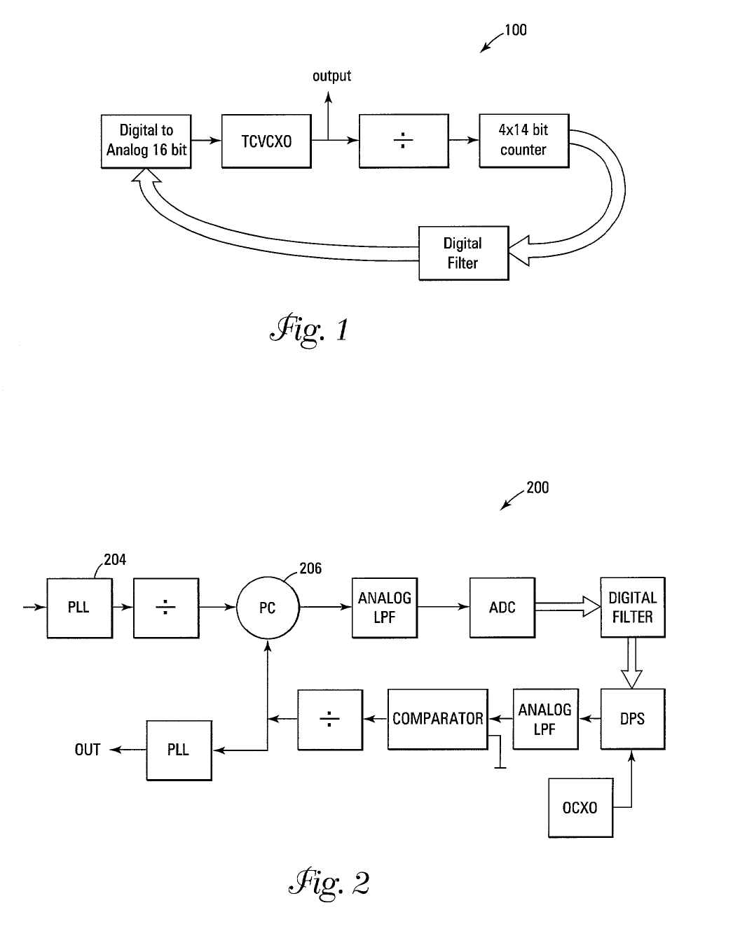

### DETAILED DESCRIPTION

In the following detailed description of the embodiments, reference is made to the accompanying drawings which form a part hereof, and in which is shown by way of illustration specific embodiments in which the invention may be practiced. It is to be understood that other embodiments may be utilized and structural or logical changes may be made without departing from the scope of the present invention.

Some portions of the detailed descriptions which follow are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like. It should be borne in mind, however, that all of these and similar terms are to be associated with the appropriate physical quantities and are merely convenient labels applied to these quantities.

Unless specifically stated otherwise as apparent from the following discussions, it is appreciated that throughout the present invention, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

The embodiments of the present invention include a synchronization module that generates a high frequency signal following a lower frequency reference clock. The embodiments remain stable as the reference frequency falls. In various embodiments, this is accomplished in a digital environment, allowing the embodiments of the present invention to utilized less expensive components and a less complex structure to perform the same functions as the prior art.

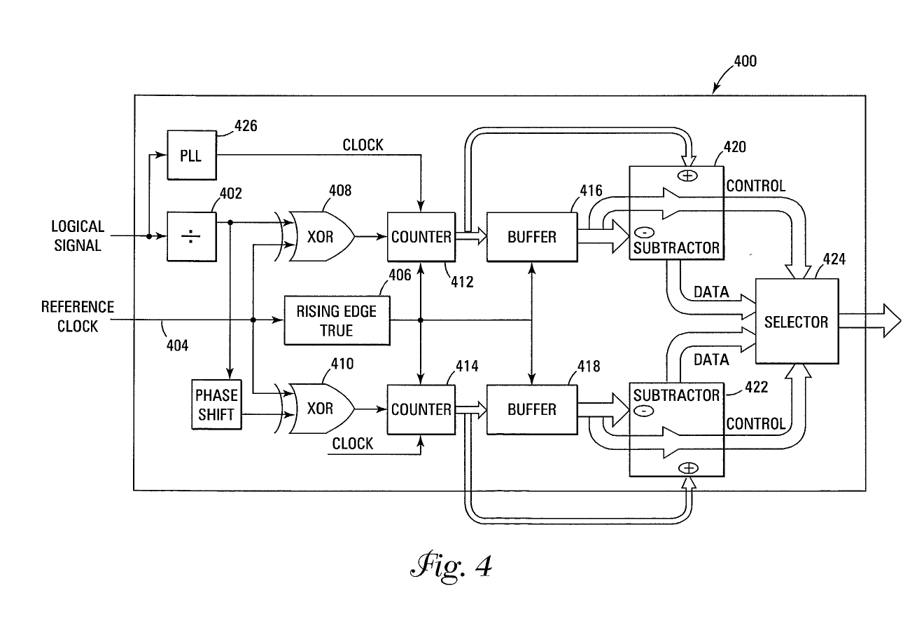

FIG. 3 is a block diagram of a synchronization circuit 300 according to one embodiment of the present invention. Circuit 300 comprises a direct digital synthesizer (DDS) block 302 comprising a digital synthesizer 304, a filter 306 and a comparator 308. DDS 302 receives input signals 310 and 312, which are a number reference and a clock respectively. The number reference is generated by digital filter 314. PLL 316 generates the clock. In normal mode, when the reference clock 324 is active, the number reference is a number proportional to the difference between the frequency of reference clock 324 and the signal 326 generated from divider 320. In free running and holdover modes, when the reference clock 324 falls, the digital filter 314 calculates the number reference using the true clock frequency estimation produced by the temperature module 322. Frequency to number converter 318 is connected between divider 320 and digital filter 314. Frequency to number converter 318 has as its inputs reference clock 324 and signal 326 from divider 320.

In the digital synthesizer block, the digital synthesizer 304 receives the number reference 310 and the clock 312, and using an internal digital to analog converter generates a digitized signal 330. This signal 330 is filtered in filter 306, which in one embodiment is a band pass filter. This filtering cleans up the signal to suppress undesired products of the digitization. The filter 306 creates a cleaned up representation of an analog signal. This signal is presented to comparator 308, which converts the analog signal to a logical signal. This logical signal is presented to the divider 320, and the divided signal is compared with the reference signal 324 at frequency to number converter 318. The frequency to number converter 318 acts as a phase comparator in one embodiment, to compare the phases of the reference clock 324 and the signal 326 from the divider 320. A stable high frequency clock is tapped at the output of the DDS block 302.

In another embodiment, PLL 316 is additionally enhanced with temperature control 322. One embodiment of temperature control 322 is shown in FIG. 3A. In this embodiment, temperature control 322 comprises a crystal oscillator (XO) 350 and a temperature to number module 352 operatively connected to the crystal oscillator 350. The temperature to number module 352 monitors the temperature of crystal oscillator 350 and corrects the digital filter 314 output 310 while the reference clock 324 falls. The correction is based on a true clock frequency estimation 328 produced by the temperature module 322. This is accomplished in one embodiment by comparison of the measured temperature to a temperature table 354, which is accessible to the temperature to number module 352. The temperature table contains in one embodiment a database of information regarding a true crystal oscillator 350 frequency estimation. The adjustment according to temperature of the number reference (310) for the DDS block 302 allows the operation of the module 300 to be automatically temperature compensated while the reference clock 324 falls.

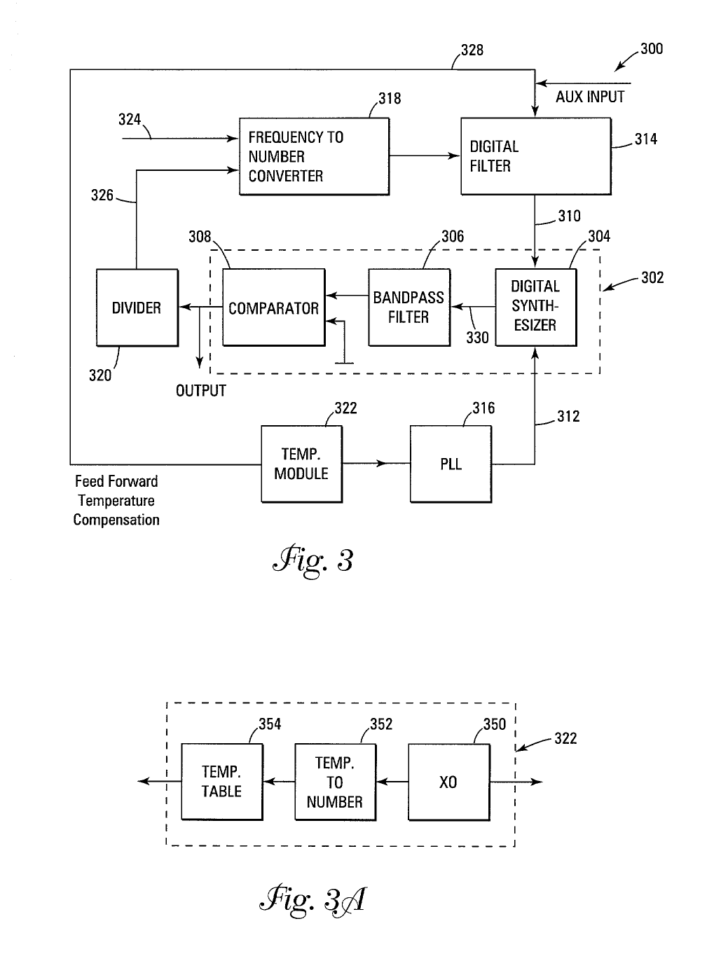

Referring back to the prior art solution of FIG. 2, the main PLL of solution 200 includes numerous components that are not necessary in the present module 300. In the solution 200, the incoming reference clock is fed through PLL 204, divided, and fed to phase comparator 206 before being converted to analog and back to digital before digital filtering. This requirement is eliminated in the module 300, which performs the work in a digital environment. Further, the low pass filter in the DDS block of the solution 200 is replaced with a band pass filter in one embodiment. The band pass filter is in one embodiment of a low order, up to a second order filter. The low pass filter of the solution 200 is a high order filter on the order of a fourth order filter. The lower order filter is acceptable due to the small changes of frequency of the reference clock 312 (usually less than 10⁻³ from the nominal value) and due to the fact that only zero crossing moments are used by the comparator 308, allowing for a big filter gain.

Frequency to number converter 318 in one embodiment is a phase comparator. It should be understood that numerous implementations of phase comparison are amenable to the operation of the embodiments of the present invention. For example, the frequency to number converters of the solutions 100 and 200 are capable frequency to number converters in the module 300.

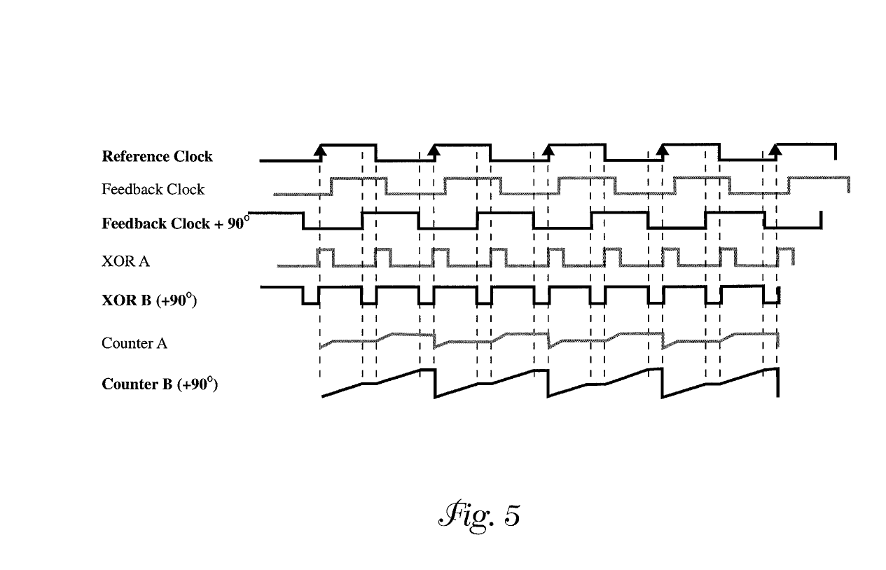

However, improved performance of frequency to number conversion is accomplished in another embodiment 400 as is shown in FIG. 4. In this embodiment, the phase difference of the two input signals, the reference clock and the divided output from the DDS block, is converted to the frequency difference using phase buffers and subtractors. The two parallel working phase difference estimators use XOR functions with the initial and 90 degree shifted DDS clock. This allows resolution of the “dead zone” problems with the estimator working far from the “dead zone.” The choice is implemented by the selector. The frequency to number converter 400 uses a reference clock such as reference clock 324 and a logical signal such as signal 326 as its inputs. The logical signal is divided in divider 402 to a frequency equal to the reference clock 404, in one embodiment 8 KHz.

The reference clock is fed to rising edge true block 406 and to one of the inputs of each of two exclusive OR (XOR) gates 408 and 410. The divided logical signal is fed to the other input of first XOR gate 408, and a 90 degree phase shifted divided logical signal is fed to the other input of second XOR gate 410. The output of first XOR gate 408 is connected to first counter 412 and the output of second XOR gate 410 is connected to second counter 414. The counters are reset on a rising edge true output from rising edge true block 406, and are clocked with clocks generated from PLL 426, the clocks being phase shifted with respect to one another, with the signal clocking counter 414 shifted positive 90 degrees with respect to the signal clocking counter 412. The counter outputs are buffered in buffers 416 and 418 respectively. The counter information and the buffered counter information are sent to subtractors 420 and 422, which each provide data and control information to selector 424. The selector 424 selects a signal for digital filtering to provide the number proportional to the difference in frequencies provided to the frequency to number converter.

This embodiment uses two counters, which need not be synchronous as in solution 100. This solution also eliminates the need for two external PLLs, further reducing cost and complex circuitry for performing operations that are no longer needed.

A timing diagram for the frequency to number converter 400 is shown in FIG. 5.

Various components of the module 300 are implemented as hardware, software, firmware, or combinations thereof. In one embodiment of frequency to number converter 400, buffers 416 and 418, subtractors 420 and 422, and selector 424 are implemented in software. In that embodiment, the divider 402, rising edge true block 406, XOR gates 408 and 410, and counters 412 and 414 are hardware based. Similarly, the digital filter 314 in one embodiment of module 300 is software based, and the remaining components are hardware based. It should be understood that other implementations of the various components are in software, hardware, firmware, or combinations thereof, and are within the scope of the present invention.

In operation, the module 300 works as follows. A reference clock 324 is fed to frequency to number converter 318. Frequency to number converter 318 uses the reference clock signal and a divided down logical signal as inputs, comparing the frequencies of the two signals as described above with respect to FIG. 4. The output from frequency to number converter 318 is digitally filtered with filter 314 to generate a filter output of a number 320. The number 320 is proportional to the frequency difference between the reference clock 324 and the divided down logical signal 326. The divided down logical signal 326 is generated by DDS block 302 and divider 320. The number 320 is an input of the DDS block 302, which is clocked by the output 312 of a PLL 316. More specifically, the number 320 and the PLL clock signal 312 are supplied to the digital synthesizer 304 of DDS block 302.

The digital synthesizer 304 has an internal digital to analog converter which converts the number into an analog waveform 330. This waveform is run through filter 306, which in one embodiment is a band pass filter, to remove the products of digitization that are undesirable in the analog signal 330. The cleaned up signal from the filter 306 is used as an input to comparator 308. Comparator 308 converts the filtered analog signal to a logical signal, which is presented as the input 326 to frequency to number converter 318. The logical signal 326 and the reference clock signal 324 are then run through the frequency to number converter in a loop to synchronize the two signals.

The methods and software components shown in FIGS. 2, 3, 3A, 4, and 5 may be implemented in whole or in part in various embodiments in a machine readable medium comprising machine readable instructions for causing a computer or processor to perform the methods and to implement the components. The computer programs run on a processing unit or in an application specific integrated circuit (ASIC) or the like, or may be run on a computer processor out of main memory, and may be transferred to main memory from permanent storage via disk drive or CD-ROM drive when stored on removable media or via a network connection or modem connection when stored outside of the computer, or via other types of computer or machine readable media from which it can be read and utilized.

Such machine readable media may include software modules and computer programs. The computer programs may comprise multiple modules or objects to perform the methods or the functions of various components. The type of computer programming languages used to write the code may vary between procedural code type languages to object oriented languages. The files or objects need not have a one to one correspondence to the modules or method steps described depending on the desires of the programmer. Further, the method and apparatus may comprise combinations of software, hardware and firmware as is well known to those skilled in the art.

It is to be understood that the above description is intended to be illustrative, and not restrictive. Many other embodiments will be apparent to those of skill in the art upon reading and understanding the above description. The scope of the invention should, therefore, be determined with reference to the appended claims, along with the full scope of equivalents to which such claims are entitled.

What is claimed is:

1. A method for generating stable high frequency signal from a low frequency reference clock signal, comprising:
receiving the reference clock signal and a divided down high frequency signal at a frequency to number converter;
generating a number in the frequency to number converter that is proportional to a difference in frequency between the divided down high frequency signal and the reference clock; and
generating a new high frequency signal from the number.

2. The method of claim 1, wherein generating a new high frequency signal comprises:
converting the number to an analog representation in a digital synthesizer;
filtering the analog representation in a band pass filter; and
converting the filtered analog representation to a logical signal.

3. The method of claim 1, and further comprising:
dividing the logical signal by a predetermined divider factor; and
feeding the divided logical signal back to the frequency to number converter.

4. The method of claim 1, and further comprising:
clocking the digital synthesizer with a phase locked loop (PLL) clock signal.

5. The method of claim 4, and further comprising:
adjusting the digital filter output to the true clock frequency estimation when the reference clock falls and the ambient temperature varies.

6. The method of claim 5, w here in adjusting the digital filter output comprises:
using a lookup table representing the changes of true crystal oscillator frequency with temperature.

7. A method for generating a stable clock signal from an external reference clock, comprising:
receiving the reference clock signal at a signal to number converter;
converting the reference clock to a number proportional to a frequency difference between the reference clock signal and a generated clock signal;
receiving the number at a direct digital synthesizer (DDS);
generating an analog representation of the number;
filtering the analog representation of the number;
converting the filtered analog representation to a logical output signal;
dividing the logical signal frequency to the frequency of the reference clock; and
feeding the divided down logical signal to the frequency to number converter.

8. The method of claim 7, and further comprising:
clocking the DSS with a PLL clock signal.

9. The method of claim 7, wherein filtering is accomplished in a band pass filter.

10. A direct digital synthesizer, comprising:
a digital synthesizer having a data input, a clock input, and an output;
a band pass filter connected to the output of the digital synthesizer; and
a comparator connected to an output of the band pass filter.

11. A temperature compensated direct digital synthesizer (DDS), comprising:
a digital synthesizer having a data input, a clock input, and an output;
a band pass filter connected to the output of the digital synthesizer;
a comparator connected to an output of the band pass filter;
a temperature module providing a feed forward temperature compensation (FFTC) signal from a look-up table to adjust the data input to the digital synthesizer, the FFTC signal indicative of frequency changes due to temperature while a reference clock falls.

12. The temperature compensated DDS of claim 11, wherein the FFTC is coupled to a digital filter coupled to the input of the digital synthesizer.

13. The temperature compensated DDS of claim 12, wherein the temperature module comprises:
a crystal oscillator having an output and a temperature sensor;
a temperature to number converter to provide a number representative of a crystal oscillator temperature; and
a lookup table accessible by the temperature to number converter, the temperature table comprising a database of the true crystal oscillator frequency versus temperature.

14. A synchronization module, comprising:
a direct digital synthesizer (DDS) having a first input and a clock input, and an output;
a frequency to number converter having a first and a second input, the first input connectable to a reference clock signal, and an output;
a digital filter connected between the DDS and the frequency to number converter output;
a divider connected between the DDS output and the second input of the frequency to number converter; and
a first phase locked loop for generating a clock signal, the clock signal connected to the clock input of the DDS.

15. The synchronization module of claim 14, wherein the DDS comprises:
a digital synthesizer having a data input, a clock input, and an output;
a filter connected to the output of the digital synthesizer; and
a comparator connected to an output of the filter.

16. The synchronization module of claim 15, wherein the filter is a band pass filter.

17. The synchronization module of claim 14, wherein the frequency to number converter comprises:
a divider having an input connected to the second frequency to number converter input and an output;
a first and a second exclusive OR (XOR) gate, each having first and second XOR inputs, the first XOR gate first input connected to the divider output, and the first XOR gate second input connected to the first frequency to number converter input;
a phase shifter connected between the divider output and the first XOR gate first input, the second XOR gate input connected to the first frequency to number converter input;
a rising edge true logic block connected to the first frequency to number converter input;
a first and a second counter, the first counter having an input connected to the output of the first XOR gate, and the second counter having a first input connected to the output of the second XOR gate, the output of the rising edge true logic block to reset the first and the second counter;
a second phase locked loop connected to the second frequency to number converter input, the second phase locked loop creating a clock signal that clocks the first and the second counters;
a first and a second subtractor and a first and a second buffer, the first buffer connected between the first counter and the first subtractor, and the second buffer connected between the second counter and the second subtractor, the first subtractor to receive buffered data from the first buffer and raw data from the first counter, the second subtractor to receive buffered data from the second buffer and raw data from the second counter; and
a selector connected between the frequency to number converter output and the first and second subtractors.

18. The synchronization module of claim 17, wherein the first and second buffer, the first and second subtractor, and the selector are implemented in software.

19. The synchronization module of claim 14, and further comprising:
a feed forward temperature compensator (FFTC) signal connected to an auxiliary input of the digital filter.

20. The synchronization module of claim 19, wherein a temperature module generates the FFTC signal.

21. The synchronization module of claim 20, wherein the temperature module comprises:
a crystal oscillator (CO) having an output and a temperature sensor;
a temperature to number converter to provide a number representative of the crystal oscillator temperature; and
a lookup table accessible by the temperature to number converter, the temperature table comprising a database of compensation factors for CO temperature.

22. A frequency to number converter, comprising:
a first and a second converter input, the first input connectable to a reference clock signal, the second input connectable to a generated clock signal, and an output;
a divider having an input connected to the second converter input, and an output;
a first and a second exclusive OR (XOR) gate, each having first and second XOR inputs, the first XOR gate first input connected to the divider output, and the first XOR gate second input connected to the first converter input;
a phase shifter connected between the divider output and the first XOR gate first input, the second XOR gate input connected to the first converter input;
a rising edge true logic block connected to the first converter input;
a first and a second counter, the first counter having an input connected to the output of the first XOR gate, and the second counter having an input connected to the output of the second XOR gate, the output of the rising edge true logic block to reset the first and the second counter;
a phase locked loop connected to the second frequency to number converter input, the phase locked loop creating a clock signal that clocks the first and the second counters;
a first and a second subtractor and a first and a second buffer, the first buffer connected between the first counter and the first subtractor, and the second buffer connected between the second counter and the second subtractor, the first subtractor to receive buffered data from the first buffer and raw data from the first counter, the second subtractor to receive buffered data from the second buffer and raw data from the second counter; and
a selector connected between the frequency to number converter output and the first and second subtractors.

23. The frequency to number converter of claim 22, wherein the first and the second buffers, the first and the second subtractors, and the selector are implemented in software.
